(19) United States
(12) Patent Application Publication
(10) Pub. No.: US 2025/0153975 A1
(43) Pub. Date: May 15, 2025

(54) Article Transport Vehicle

(71) Applicant: Daifuku Co., Ltd., Osaka-shi (JP)

(72) Inventor: Hiroshi Otsuka, Hinocho (JP)

(21) Appl. No.: 18/941,072

(22) Filed: Nov. 8, 2024

(30) Foreign Application Priority Data
Nov. 10, 2023 (JP) 2023-192506

(51) Int. Cl. B66C 13/16; B66C 15/06

(52) U.S. Cl. CPC B66C 13/16; B66C 15/065

(57) ABSTRACT

An article transport vehicle includes a holder that holds an article, a lifter that raises and lowers the holder, and a control device that controls the lifter. The lifter includes a rotator, a wound member windable around and unwindable from the rotator, and a lifter drive motor that rotates the rotator. The control device includes a transmission torque detector that detects transmission torque transmitted from the lifter drive motor to the rotator and a weight estimator that estimates a weight of the article based on the detected transmission torque.

### CROSS-REFERENCE TO RELATED APPLICATION

This application claims priority to Japanese Patent Application No. 2023-192506 filed Nov. 10, 2023, the disclosure of which is hereby incorporated by reference in its entirety.

### BACKGROUND OF THE INVENTION

### Field of the Invention

The present invention relates to an article transport vehicle.

### Description of Related Art

Article transport vehicles for transporting articles are available. An example of such article transport vehicles is described in Japanese Unexamined Patent Application Publication No. 2020-200145 (JP 2020-200145).

JP 2020-200145 describes an article transport vehicle (crane 1) that includes a holder (claws 30) for holding an article (to be transported), a lifter (winder 22) for raising and lowering the holder, and a control device (controller 44) that controls the lifter. The lifter includes a wound member (wire rope 23) that is windable and unwindable and a lifter drive motor (motor 41) that rotates a rotator around which the wound member is wound. The control device monitors the torque of the lifter drive motor.

In the article transport vehicle described in JP 2020-200145, the control device monitors the torque of the lifter drive motor and simply stops the rotation of the lifter drive motor urgently in response to detection of the motor torque exceeding a predetermined threshold (threshold L). More specifically, the technique described in JP 2020-200145 is simply a fail-safe for preventing an abnormality. However, the article transport vehicle may be efficiently operated by more actively using the torque of the lifter drive motor.

### SUMMARY OF THE INVENTION

One or more aspects are directed to an article transport vehicle that is efficiently operable using the torque of a lifter drive motor.

An article transport vehicle according to an aspect of the disclosure is an article transport vehicle for transporting an article. The article transport vehicle includes a holder that holds the article, a lifter that raises and lowers the holder, and a control device that controls the lifter. The lifter includes a rotator, a wound member windable around and unwindable from the rotator, and a lifter drive motor that rotates the rotator. The lifter raises and lowers the holder suspended with the wound member by winding and unwinding the wound member with rotation of the rotator. The control device includes a transmission torque detector that detects transmission torque transmitted from the lifter drive motor to the rotator, and a weight estimator that estimates a weight of the article held by the holder based on the transmission torque detected by the transmission torque detector.

This structure detects the transmission torque transmitted from the lifter drive motor to the rotator and estimates the weight of the article held by the holder in various situations based on the transmission torque. The weight estimation results of the article obtained in this manner can be used to efficiently operate the article transport vehicle.

Further features and advantageous effects of the technique according to the disclosure will be apparent from exemplary and nonlimiting embodiments described below with reference to the drawings.

### BRIEF DESCRIPTION OF THE DRAWINGS

FIG. 1 is a side view of an article transport facility according to a first embodiment.

FIG. 2 is a side view of an article transport vehicle.

FIG. 3 is a front view of the article transport vehicle.

FIG. 4 is a perspective view of a lifter.

FIG. 5 is a block diagram of a control system.

FIG. 6 is a flowchart of a drop determination process.

FIG. 7 is a time chart of the lift speed of a holder and the torque of a lifter drive motor.

FIG. 8 is a schematic diagram of a holder in an article transport vehicle according to a second embodiment.

FIG. 9 is a block diagram of a control system.

FIG. 10 is a flowchart of a lowering adjustment process.

### DESCRIPTION OF THE INVENTION

### First Embodiment

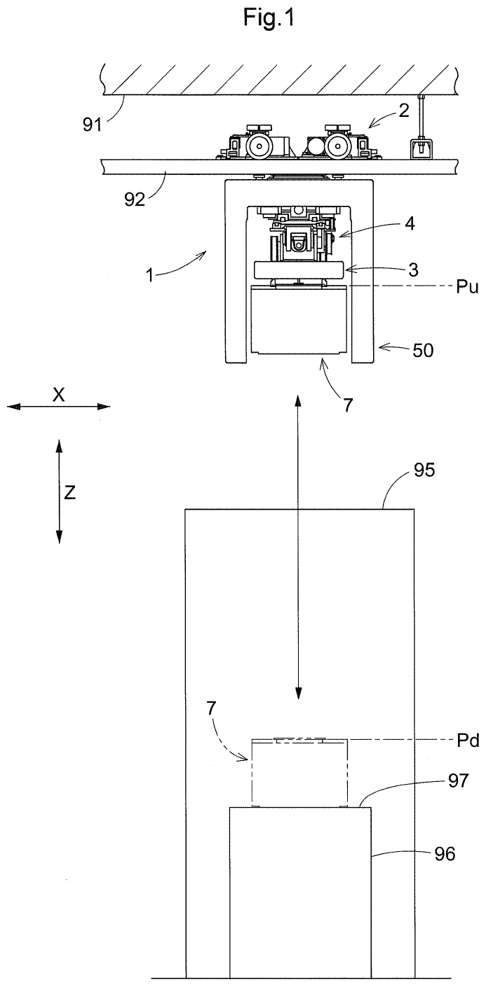

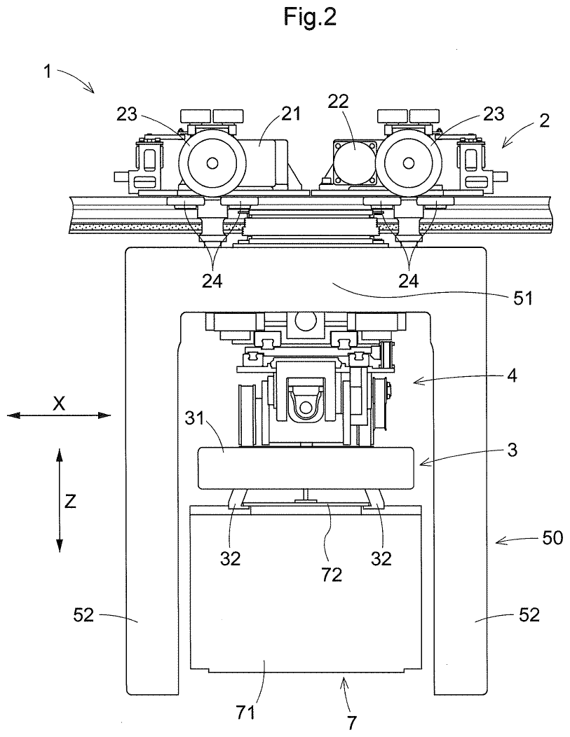

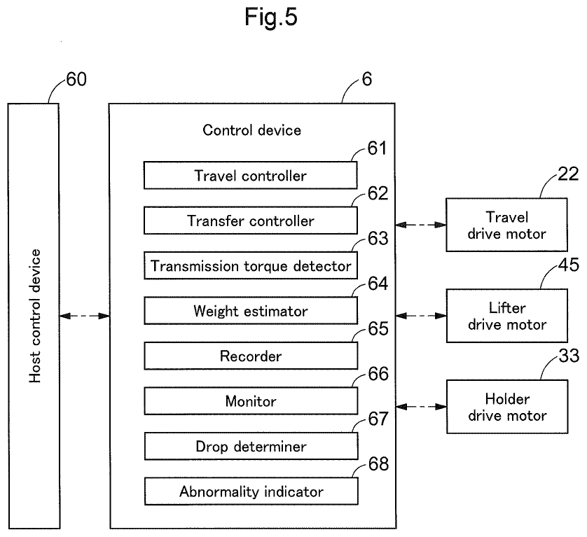

An article transport vehicle according to a first embodiment will be described with reference to the drawings. An article transport vehicle 1 according to the present embodiment is used to transport an article 7 at, for example, a semiconductor manufacturing plant. As shown in FIGS. 1 and 2, the article transport vehicle 1 includes a traveler 2, a holder 3, and a lifter 4. The article transport vehicle 1 also includes a control device 6 (refer to FIG. 5) for controlling the traveler 2, the holder 3, and the lifter 4.

The traveler 2 travels along the travel path. The holder 3 and the lifter 4 are connected to the traveler 2 and hung from the traveler 2. In the structure, the entire article transport vehicle 1 travels along the travel path. In the present embodiment, the travel path of the article transport vehicle 1 is physically defined by rails 92 hung from a ceiling 91. More specifically, the article transport vehicle 1 according to the present embodiment is a ceiling-hung transport vehicle that moves along the rails 92 extending parallel to the ceiling 91.

The article 7 to be transported by the article transport vehicle 1 may be, but is not limited to, wafer containers (front-opening unified pods, or FOUPs) containing wafers or reticle containers (reticle pods) containing reticles. As shown in FIG. 2, the article 7 in the present embodiment includes a container 71 and a flange 72 at the top of the container 71.

For example, the article transport vehicle 1 transports the article 7 onto a mount 96 of a processing device 95 disposed below the travel path. The article transport vehicle 1 transports the article 7 and lowers the article 7 with the lifter 4 to load the article 7 onto a transfer area 97 (e.g., an upper surface) of the mount 96. The article transport vehicle 1 holding the article 7 in the transfer area 97 on the mount 96 raises the article 7 with the lifter 4 to unload the article 7 from the transfer area 97. The transfer area 97 may be at the same level throughout the transfer area 97 or at different levels at different positions of the transfer area 97.

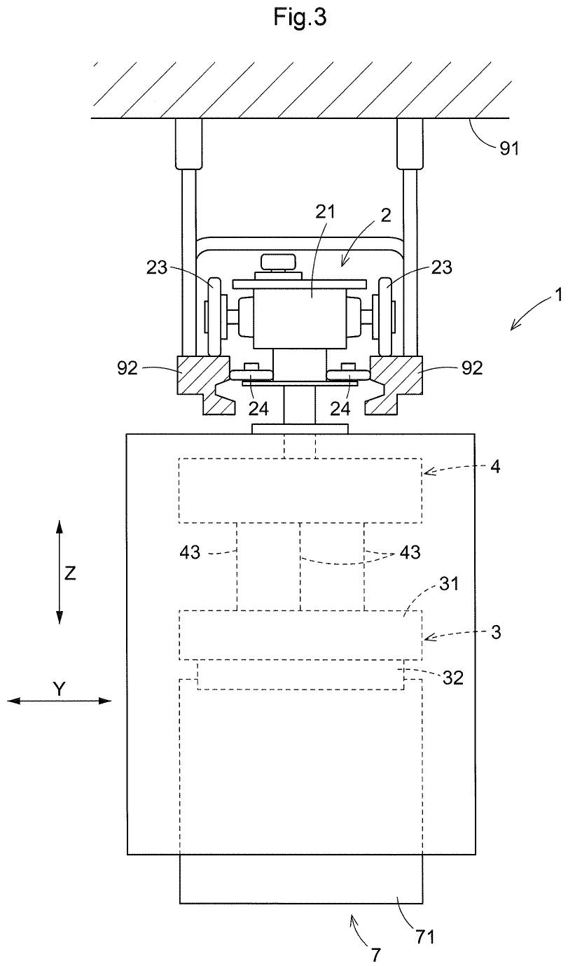

The traveler 2 travels along the rails 92 as a pair. As shown in FIGS. 2 and 3, the traveler 2 includes a body 21, a travel drive motor 22, wheels 23, and guide wheels 24. The body 21 supports, for example, the travel drive motor 22, the wheels 23, and the guide wheels 24. The travel drive motor 22 includes an electric motor such as a servomotor to drive at least one of the wheels 23. The wheels 23 roll on the upper surfaces of the rails 92. The wheels 23 are connected to the travel drive motor 22 to function as drive wheels. The guide wheels 24 roll on the inner surfaces of the rails 92. The traveler 2 travels on the rails 92 along the rails 92, with the guide wheels 24 in contact with and guided by the inner surfaces of the rails 92.

The direction along the rails 92, or the direction in which the traveler 2 travels, is hereafter referred to as a front-rear direction X for the article transport vehicle 1. The direction perpendicular to the front-rear direction X and parallel to the direction in which the pair of rails 92 are arranged is referred to as a lateral direction Y for the article transport vehicle 1. The direction perpendicular to both the front-rear direction X and the lateral direction Y is referred to as a vertical direction Z. These directions are defined with respect to the article transport vehicle 1. The front-rear direction X and the lateral direction Y may be in different directions based on the position of the article transport vehicle 1 along the path when viewed from a fixed point in the facility. The vertical direction Z is aligned with the vertical direction.

The holder 3 and the lifter 4 are arranged below the rails 92. The lifter 4 is accommodated in a cover 50 hung from the traveler 2. The holder 3 is accommodated in the cover 50 at an uppermost position Pu in the lift range. The cover 50 includes an upper cover portion 51 covering the upper area and a pair of side cover portions 52 covering opposite areas in the front-rear direction X. The internal space of the cover 50 is open in at least one of opposite areas (in both areas in this example) in the lateral direction Y.

The holder 3 holds the article 7. As shown in FIGS. 2 and 3, the holder 3 includes a connector 31, article supports 32, and a holder drive motor 33 (refer to FIG. 5). The connector 31 is connected to the lifter 4. In the present embodiment, the connector 31 serves as a base (holder body) of the holder 3. The connector 31 supports the article supports 32 in a manner slidable in the front-rear direction X. The connector 31 supports the holder drive motor 33 in a fixed manner.

The article supports 32 come in contact with and support the article 7. The article supports 32 in the present embodiment support the flange 72 on the article 7 from below. In the present embodiment, the article supports 32 as a pair together support the flange 72 on the article 7 on both ends in the front-rear direction X. The pair of article supports 32 are arranged at a predetermined interval in the front-rear direction X. The pair of article supports 32 are each slidable in the front-rear direction X and move toward or away from each other in the front-rear direction X.

The holder drive motor 33 moves the pair of article supports 32 in the front-rear direction X. The holder drive motor 33 is connected to the pair of article supports 32 with, for example, a ball screw. The holder drive motor 33 moves the pair of article supports 32 in the opposite directions toward or away from each other in the front-rear direction X.

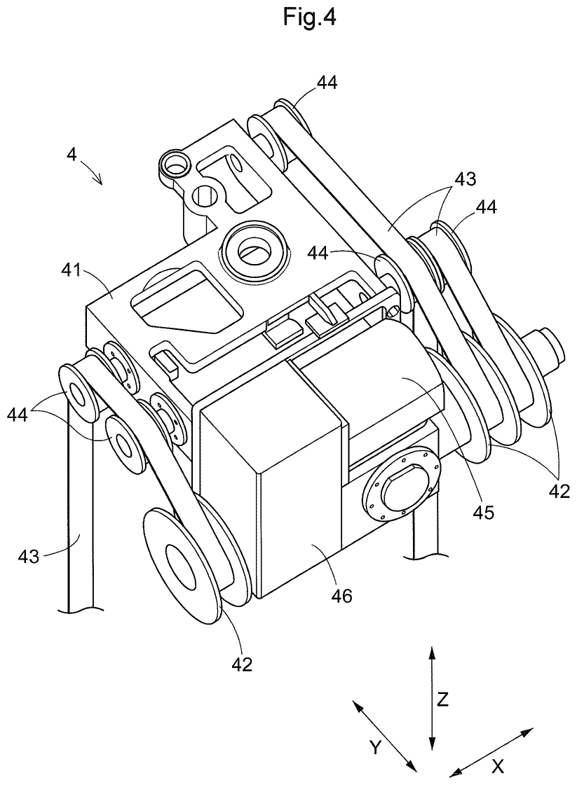

The lifter 4 raises and lowers the holder 3. As shown in FIG. 4, the lifter 4 includes a base 41, rotators 42, wound members 43, pulleys 44, a lifter drive motor 45, and a transmission 46. The base 41 supports the rotators 42, the pulleys 44, the lifter drive motor 45, and the transmission 46. The rotators 42 are rotatably supported on the base 41. In the present embodiment, the multiple (three in this example) rotators 42 are coaxially arranged. The wound members 43 are windable around and unwindable from the respective rotators 42. The wound members 43 are each guided downward by one or more pulleys 44 rotatably supported on the base 41. The wound members 43 have lower ends fixed to the connector 31 in the holder 3.

The lifter drive motor 45 is connected to the rotators 42 through the transmission 46 to transmit a driving force. The lifter drive motor 45 rotates the rotators 42 to wind the wound members 43 around the rotators 42 or to unwind the wound members 43 from the rotators 42. The transmission 46 is a reducer in the present embodiment. The transmission 46 reduces the rotation of the lifter drive motor 45 and transmits the rotation to the rotators 42.

The lifter 4 with this structure raises and lowers the holder 3 suspended with the wound members 43 by winding and unwinding the wound members 43 by rotating the rotators 42.

The control device 6 controls the operation of the article transport vehicle 1. The control device 6 controls the traveler 2 (travel drive motor 22), the holder 3 (holder drive motor 33), and the lifter 4 (lifter drive motor 45) to control the operation of the article transport vehicle 1. The control device 6 is mounted on the article transport vehicle 1. The control device 6 controls the operation of the article transport vehicle 1 in response to a command from a host control device 60 installed in a control facility (not shown). The control device 6 mounted on each of multiple article transport vehicles 1 may communicate with one another.

As shown in FIG. 5, the control device 6 in the present embodiment includes a travel controller 61, a transfer controller 62, a transmission torque detector 63, a weight estimator 64, a recorder 65, a monitor 66, a drop determiner 67, and an abnormality indicator 68. The control device 6 includes an arithmetic processor such as a central processing unit (CPU) and a main storage such as a random-access memory (RAM) or a read-only memory (ROM). The functional units of the control device 6 are implemented by the arithmetic processor and a program executed on the arithmetic processor cooperating with each other.

The travel controller 61 controls the travel of the traveler 2. The travel controller 61 controls the operation of the travel drive motor 22 to control the travel of the traveler 2 along the travel path.

The transfer controller 62 controls transfer of the article 7 using the holder 3. The transfer controller 62 controls the operation of the holder drive motor 33 to cause the pair of article supports 32 to support or release the flange 72 on the article 7. The transfer controller 62 controls the operation of the lifter drive motor 45 to raise or lower the holder 3. The transfer controller 62 controls the operation of the holder drive motor 33 and the operation of the lifter drive motor 45 in a cooperative manner to control the transfer of the article 7.

The transmission torque detector 63 detects transmission torque transmitted from the lifter drive motor 45 to the rotators 42 (hereafter simply referred to as transmission torque). In the present embodiment, the transmission torque detector 63 detects the motor torque based on the motor current flowing through the lifter drive motor 45 and detects the transmission torque based on the obtained motor torque. In the structure including the transmission 46 between the rotators 42 and the lifter drive motor 45 as in the present embodiment, the transmission torque detector 63 detects the transmission torque as a value obtained by multiplying the motor torque by the variable speed ratio.

Although the transmission torque may be detected at any time, the transmission torque detector 63 may detect the transmission torque with the lifter 4 stopping raising or lowering the holder 3. With the lifter 4 stopping raising or lowering the holder 3, the motor current flowing through the lifter drive motor 45 is used simply for supporting the article 7. This reduces noise and allows accurate detection of the transmission torque.

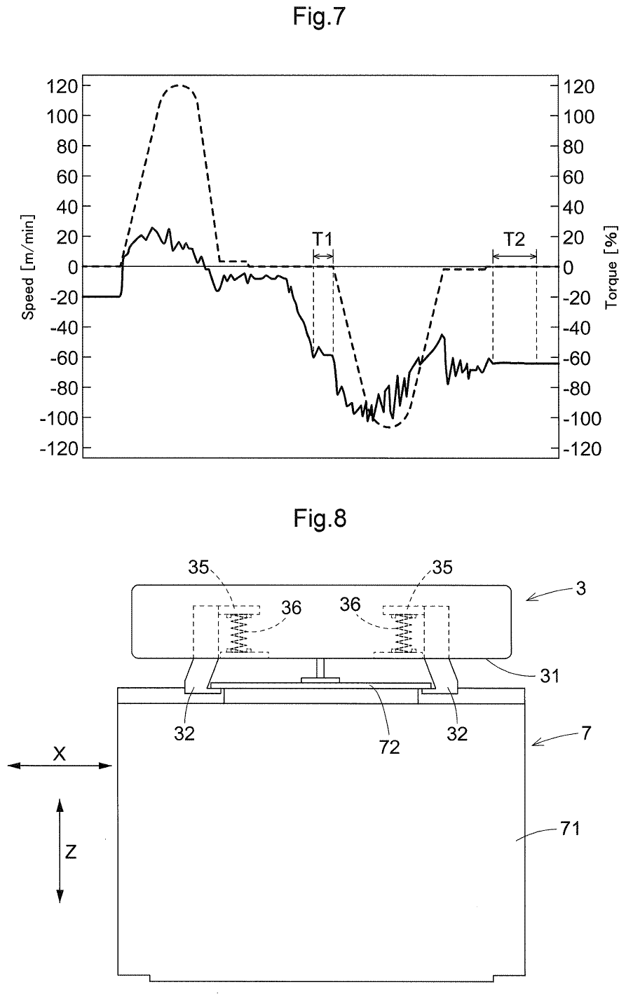

In the example in FIG. 7, the transmission torque detector 63 may detect the transmission torque in a first period T1 or a second period T2 in which the lift speed of the holder 3 is zero. In FIG. 7, the lift speed of the holder 3 has a positive value indicating a lowering speed and an absolute value of a negative value indicating a raising speed. The torque of the lifter drive motor 45 has a positive value indicating the torque in the direction of lowering the holder 3 and has an absolute value of a negative value indicating the torque in the direction of raising the holder 3. These values are expressed as the percentage of the rated torque. The horizontal axis indicates time.

The first period T1 corresponds to the period for which the lowered holder 3 first supports the article 7 placed on the transfer area 9. In the first period T1, the holder 3 is stationary at a lowermost position Pd (refer to FIG. 1) in the lift range of the holder 3. The lowermost position Pd in the lift range of the holder 3 is determined as appropriate for the vertical position of the transfer area 97. The second period T2 corresponds to the period for which the holder 3 holding the article 7 and raised again stably supports the article 7 in the cover 50. In the second period T2, the holder 3 is stationary at the uppermost position Pu (refer to FIG. 1) in the lift range of the holder 3.

Although the transmission torque is detected at any position, the transmission torque detector 63 may detect the transmission torque with the holder 3 being stationary at the uppermost position Pu in the lift range of the holder 3. When the holder 3 is stationary at the uppermost position Pu, the wound members 43 are wound around the rotators 42 by the maximum length to have the maximum radius. This increases the transmission torque and relatively reduces noise effects. Thus, the transmission torque can be detected with high accuracy.

The weight estimator 64 estimates the weight of the article 7 held by the holder 3 based on the transmission torque detected by the transmission torque detector 63. With the holder 3 holding the article 7 with the torque from the lifter drive motor 45, the wound members 43 wound around the rotators 42 have a power balance described below.

$$Transmission torque = ( radius of wound members 43 ) \times ( force acting on article 7 ) \qquad ( A )$$

The radius of the wound members 43 is defined as the sum of the radius of the rotators 42 and the total thickness of the wound members 43 wound around the rotators 42. The force acting on the article 7 is defined as the product of the weight of the article 7 and the gravity acceleration. Thus, the weight of the article 7 is calculated based on the above Formula A using the transmission torque detected by the transmission torque detector 63 and the radius of the wound members 43 as variables. The weight estimator 64 estimates the calculated value as the weight of the article 7.

In the structure in the present embodiment in which the transmission torque detector 63 detects the transmission torque with the holder 3 being stationary at the uppermost position Pu, the radius of the wound members 43 can be used as a constant. Thus, the weight estimator 64 can practically estimate the weight of the article 7 using the transmission torque alone as a variable. The radius of the wound members 43 with the holder 3 being stationary at the uppermost position Pu may be obtained through measurement and prestored as a predetermined value.

When the holder 3 is stationary at the uppermost position Pu, the article 7 is accommodated in the cover 50. The article 7 may be transported by the article transport vehicle 1 in this state. In this case, vibrations resulting from the travel of the article transport vehicle 1 (e.g., vibrations resulting from travel path conditions such as bumps in the rails 92 and branching or merging of the rails 92 or vibrations caused by, for example, the wheels 23 or the drive transmission system of the article transport vehicle 1) may adversely affect the detection of the transmission torque and thus the weight estimation of the article 7. The weight estimator 64 may thus estimate the weight of the article 7 based on the value obtained by applying a low-pass filter to the detection value of the transmission torque obtained by the transmission torque detector 63.

Before the article transport vehicle 1 (traveler 2) starts traveling, the recorder 65 records the weight of the article 7 estimated by the weight estimator 64 as a prestart weight. The recorder 65 has a temporary storage area allocated in the main storage in the control device 6. The recorder 65 records the prestart weight into the temporary storage area.

The monitor 66 continuously monitors the weight of the article 7 estimated by the weight estimator 64 during travel of the article transport vehicle 1 (traveler 2). The monitor 66 records the weight of the article 7 estimated by the weight estimator 64 into the temporary storage area allocated in the main storage in the control device 6 at predetermined time intervals.

When the difference between the latest estimated weight of the article 7 monitored by the monitor 66 and the prestart weight is greater than or equal to a predetermined threshold, the drop determiner 67 determines that at least a part of the article 7 has dropped. The prestart weight and the latest estimated weight of the article 7 are both recorded in the temporary storage area in the main storage in the control device 6. The drop determiner 67 monitors the weight difference of the article 7 from before the start of the travel based on these weights. The threshold for the determination may be set to, based on the weight of a part of the article 7 (e.g., a container lid or a contained object), a slightly less value than the weight. In response to the weight difference of the article 7 from before the start of the travel being greater than or equal to the determination threshold, the drop determiner 67 determines that at least a part of the article 7 has dropped and notifies the abnormality indicator 68 of the dropping.

In response to receiving the notification resulting from the drop determination from the drop determiner 67, the abnormality indicator 68 indicates an abnormality in the article 7 being transported by the article transport vehicle 1. The abnormality indicator 68 can indicate the abnormality by, for example, displaying the abnormality on a monitor of a control computer or outputting, for example, an alarm sound from a speaker.

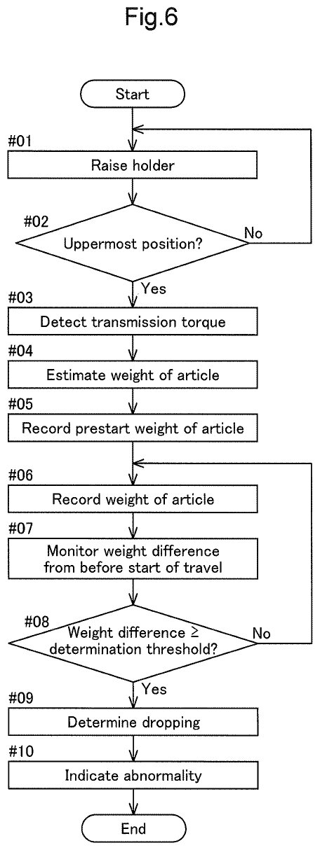

A drop determination process performed in the article transport vehicle 1 according to the present embodiment will now be described. In the present embodiment, the detection of the transmission torque and the weight estimation of the article 7 are performed at the uppermost position Pu. As shown in FIG. 6, the holder 3 holding the article 7 is first raised (step #01). The determination is then performed as to whether the holder 3 is stationary at the uppermost position Pu (#02). The holder 3 is raised continuously until the holder 3 is determined to be stationary at the uppermost position Pu (Yes in #02).

With the holder 3 being stationary at the uppermost position Pu, the transmission torque detector 63 detects transmission torque transmitted from the lifter drive motor 45 to the rotators 42 (#03). The weight estimator 64 estimates, based on the detected transmission torque, the weight of the article 7 held by the holder 3 (#04). The detection of the transmission torque and the weight estimation of the article 7 based on the transmission torque detection are performed continuously at predetermined time intervals.

In the present embodiment, the weight of the article 7 estimated before the article transport vehicle 1 (traveler 2) starts traveling is recorded as the prestart weight into the recorder 65 (#05). After the article transport vehicle 1 (traveler 2) starts traveling, the monitor 66 continuously records the estimated weight of the article 7 (#06). The monitor 66 continuously monitors, based on the prestart weight and the latest estimated weight of the article 7, the weight difference from before the article transport vehicle 1 (traveler 2) starts traveling (#07).

The drop determiner 67 determines whether the weight difference from before the start of the travel is greater than or equal to a predetermined determination threshold (#08). When the weight difference is less than the determination threshold (No in #08), no abnormality such as dropping is determined to have occurred, and the weight difference is continuously monitored. When the weight difference is greater than or equal to the determination threshold (Yes in #08), the drop determiner 67 determines that at least a part of the article 7 has dropped (#09). The abnormality indicator 68 indicates the abnormality in the article 7 being transported (#10).

### Second Embodiment

An article transport vehicle according to a second embodiment will be described with reference to the drawings. The article transport vehicle 1 according to the present embodiment includes a holder 3 with a structure partially different from the structure of the holder 3 in the first embodiment. The control performed in the article transport vehicle 1 is thus also partially different from the control in the first embodiment. The article transport vehicle 1 according to the present embodiment will now be described focusing on the differences from the first embodiment. The components not described are the same as those in the first embodiment, and denoted with the same reference signs and will not be described in detail.

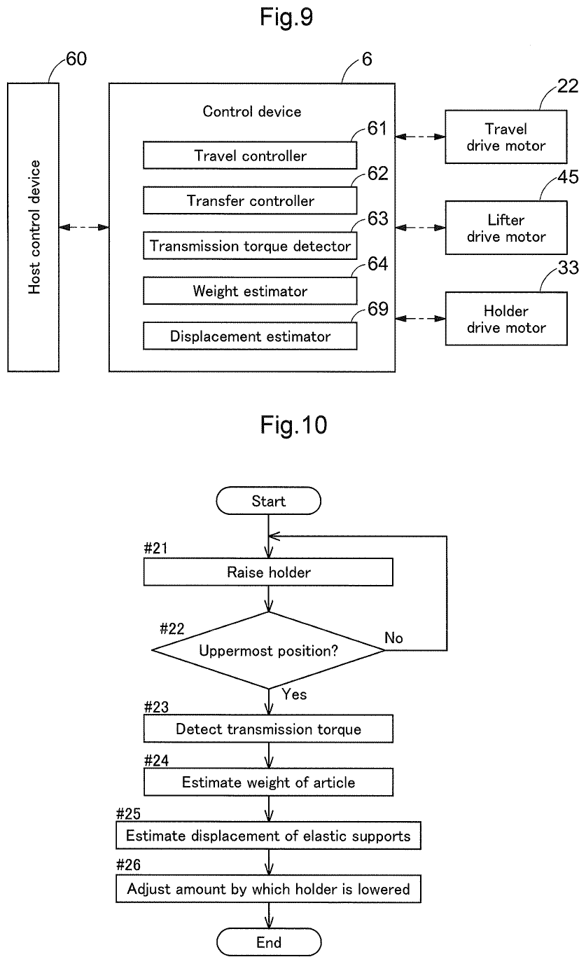

As shown in FIG. 8, the holder 3 in the article transport vehicle 1 according to the present embodiment further includes support brackets 35 and elastic supports 36 in addition to the connector 31, the article supports 32, and the holder drive motor 33 (refer to FIG. 9). The support brackets 35 as a pair correspond to the article supports 32. The support brackets 35 are connected and fixed to the respective article supports 32. The pair of support brackets 35 are arranged at a predetermined interval in the front-rear direction X. The pair of support brackets 35, together with the article supports 32, are each slidable in the front-rear direction X and move in the front-rear direction X toward or away from each other.

The elastic supports 36 are disposed above the lower end surface of the connector 31 and between the connector 31 and the support brackets 35. The elastic supports 36 support the article supports 32 in an elastic manner in the vertical direction Z with respect to the connector 31. The elastic supports 36 can attenuate, for example, vibrations of the traveler 2 caused by the traveler 2 traveling or vibrations of the holder 3 caused by the lifter 4 raising or lowering the holder 3. The article 7 can thus be supported stably with less vibration, allowing accurate weight estimation of the article 7. In the present embodiment, the elastic supports 36 are coil springs in a compressed state.

As shown in FIG. 9, the control device 6 according to the present embodiment includes the travel controller 61, the transfer controller 62, the transmission torque detector 63, the weight estimator 64, and a displacement estimator 69.

The displacement estimator 69 estimates the displacement of the elastic supports 36 in the vertical direction Z based on the weight of the article 7 estimated by the weight estimator 64. In the present embodiment, the elastic supports 36 are compressed between the connector 31 and the support brackets 35. The displacement in the vertical direction Z is the compression amount. The displacement estimator 69 estimates the displacement in the vertical direction Z based on the dimensions of the elastic supports 36 in the vertical direction Z when the holder 3 is not holding the article 7. The relationship between the weight of the article 7 and the displacement of the elastic supports 36 in the vertical direction Z is prestored. The displacement estimator 69 substitutes the weight of the article 7 estimated by the weight estimator 64 into the relational expression to estimate the displacement of the elastic supports 36 in the vertical direction Z through calculation.

The displacement of the elastic supports 36 in the vertical direction Z estimated by the displacement estimator 69 is used to transfer the article 7. To transfer the article 7 onto the transfer area 97 by lowering the holder 3 holding the article 7, the transfer controller 62 adjusts the amount by which the holder 3 is lowered by the lifter 4 based on the displacement of the elastic supports 36 in the vertical direction Z estimated by the displacement estimator 69. More specifically, the transfer controller 62 decreases the amount by which the holder 3 is lowered by the lifter 4 for a greater displacement of the elastic supports 36 in the vertical direction Z estimated by the displacement estimator 69.

A lowering adjustment process performed in the article transport vehicle 1 according to the present embodiment will now be described. In the present embodiment as well, the detection of the transmission torque and the weight estimation of the article 7 are performed at the uppermost position Pu. As shown in FIG. 10, the holder 3 holding the article 7 is first raised (step #21). The determination is then performed as to whether the holder 3 is stationary at the uppermost position Pu (#22). The holder 3 is raised continuously until the holder 3 is determined to be stationary at the uppermost position Pu (Yes in #22).

With the holder 3 being stationary at the uppermost position Pu, the transmission torque detector 63 detects transmission torque transmitted from the lifter drive motor 45 to the rotators 42 (#23). The weight estimator 64 estimates the weight of the article 7 held by the holder 3 based on the detected transmission torque (#24).

The displacement estimator 69 estimates, based on the estimated weight of the article 7, the displacement of the elastic supports 36 in the vertical direction Z (#25). When the article 7 is transferred to the transfer area 97, the transfer controller 62 adjusts the amount by which the holder 3 is lowered based on the estimated displacement of the elastic supports 36 (#26).

### Other Embodiments

(1) In the above embodiments, the transmission torque detector 63 detects the transmission torque mainly with the holder 3 being stationary at the uppermost position Pu or the lowermost position Pd in the lift range of the holder 3. However, the structure is not limited to such an example. The transmission torque detector 63 may detect transmission torque with the holder 3 being stationary at any position between the uppermost position Pu and the lowermost position Pd. In this case, the weight estimator 64 estimates the weight of the article 7 using the radius of the wound members 43 as a variable.

(2) In the above embodiments, the transmission torque detector 63 detects the transmission torque with the holder 3 being stationary. However, the structure is not limited to such an example. The transmission torque detector 63 may detect the transmission torque with the lifter 4 raising or lowering the holder 3 at a constant speed. In this case, the weight estimator 64 estimates the weight of the article 7 using the radius of the wound members 43 as a variable.

(3) In the above embodiments, the weight estimator 64 estimates the weight of the article 7 based on the value obtained by applying the low-pass filter to the detection value of the transmission torque obtained by the transmission torque detector 63. However, the structure is not limited to such an example. The weight estimator 64 may estimate the weight of the article 7 by directly using the detection value of the transmission torque obtained by the transmission torque detector 63 (in other words, without applying the filter).

(4) In the first embodiment described above, the determination threshold used as a reference by the drop determiner 67 to perform the drop determination is mainly set to a single specific value. However, the structure is not limited to such an example. The determination threshold may be set as two or more threshold values. For example, a first determination threshold may be set to perform drop determination for a part of the article 7 (e.g., a lid), and a second determination threshold greater than the first determination threshold may be set to perform drop determination for the entire article 7.

(5) In the first embodiment described above, when the drop determiner 67 determines that at least a part of the article 7 has dropped, the abnormality indicator 68 simply indicates an abnormality in the article 7 being transported. However, the structure is not limited to such an example. In addition to the abnormality indicator 68 indicating the abnormality, the travel controller 61 may immediately stop the travel of the traveler 2 in the above case.

(6) In the second embodiment described above, the elastic supports 36 are disposed above the lower end surface of the connector 31 and between the connector 31 and the support brackets 35. However, the structure is not limited to such an example. The elastic supports 36 may be disposed between the connector 31 and the support brackets 35 below the connector 31. In this case, the displacement of the elastic supports 36 in the vertical direction Z is the amount of elongation.

(7) In each of the above embodiments, the control device 6 may further include an overweight determiner that determines whether the article 7 is overweight based on the weight of the article 7 estimated by the weight estimator 64. The overweight determiner may determine that the article 7 is overweight in response to, for example, the estimated weight of the article 7 exceeding a predetermined maximum holding weight (to which a small allowance may be added). When the overweight determiner determines that the article 7 is overweight, the transfer controller 62 may release the article 7, and the travel controller 61 may stop the travel of the traveler 2. For such overweight determination, the weight estimated using the transmission torque detected in the first period T1 shown in FIG. 7 may be used to promptly determine whether the article 7 is overweight.

(8) In the above embodiments, the transmission torque detector 63 detects the transmission torque based on the motor current flowing through the lifter drive motor 45. However, the structure is not limited to such an example. For example, a torque sensor may be disposed on a power transmission path between the rotators 42 and the lifter drive motor 45 to allow the transmission torque detector 63 to detect the transmission torque.

(9) The structure described in each of the above embodiments (including the above embodiments and other embodiments; the same applies hereafter) may be combined with any other structures described in the other embodiments unless any contradiction arises. For other structures as well, the embodiments described herein are merely illustrative in all respects and may be modified as appropriate without departing from the spirit and scope of the disclosure.

### Overview of Embodiments

The article transport vehicle according to one or more embodiments of the disclosure may have the structure overviewed below.

The article transport vehicle is an article transport vehicle for transporting an article. The article transport vehicle includes a holder that holds the article, a lifter that raises and lowers the holder, and a control device that controls the lifter. The lifter includes a rotator, a wound member windable around and unwindable from the rotator, and a lifter drive motor that rotates the rotator. The lifter raises and lowers the holder suspended with the wound member by winding and unwinding the wound member with rotation of the rotator. The control device includes a transmission torque detector that detects transmission torque transmitted from the lifter drive motor to the rotator, and a weight estimator that estimates a weight of the article held by the holder based on the transmission torque detected by the transmission torque detector.

This structure detects the transmission torque transmitted from the lifter drive motor to the rotator and estimates the weight of the article held by the holder in various situations based on the transmission torque. The weight estimation results of the article obtained in this manner can be used to efficiently operate the article transport vehicle.

In one aspect, the transmission torque detector may detect the transmission torque with the lifter stopping raising or lowering the holder or with the lifter raising or lowering the holder at a constant speed.

This structure allows detection of the transmission torque with no acceleration resulting from raising or lowering of the holder performed by the lifter acting on the article, thus increasing the accuracy of weight estimation easily.

In one aspect, the transmission torque detector may detect the transmission torque with the holder being stationary at an uppermost position in a lift range of the holder.

When the holder is at the uppermost position in the lift range, the wound member is typically wound around the rotator by a larger amount. As the length of the wound member wound around the rotator increases, the outer diameter of the wound member wound around the rotator also increases, proportionally increasing the torque for supporting the article. Thus, the transmission torque detected with the article transport vehicle being stationary at the uppermost position in the lift range as described above can have a smaller detection error than the transmission torque detected with, for example, the article transport vehicle being stationary at the lowermost position in the lift range, thus increasing the accuracy of weight estimation.

In one aspect, the article transport vehicle may further include a traveler connected to the holder and the lifter. The traveler may travel along a travel path. The control device may further include a recorder that records, before the traveler starts traveling, the weight of the article estimated by the weight estimator as a prestart weight, a monitor that continuously monitors the weight of the article estimated by the weight estimator during travel of the traveler, and a drop determiner that determines that at least a part of the article has dropped in response to a difference between a latest estimated weight of the article monitored by the monitor and the prestart weight being greater than or equal to a predetermined determination threshold.

This structure allows detection of any drop of at least a part of the article through continuous monitoring of the estimation result of the weight of the article based on the detected transmission torque, without the drop detection sensor installed in the article transport vehicle. The article transport vehicle can thus have a drop detection function with a simple structure and lower costs.

In one aspect, the weight estimator may estimate the weight of the article based on a value obtained by applying a low-pass filter to a detection value of the transmission torque obtained by the transmission torque detector.

This structure reduces high-frequency components of vibrations in the article transport vehicle caused by, for example, the structure of the article transport vehicle or the conditions of the travel path, and thus reduces variations in the estimated weight value of the article. This easily increases the accuracy of the drop determination of the article.

In one aspect, the holder may include an article support that is to be in contact with the article to support the article, a connector connected to the lifter, and an elastic support supporting the article support in a vertically elastic manner with respect to the connector. The control device may further include a displacement estimator that estimates a vertical displacement of the elastic support based on the weight of the article estimated by the weight estimator.

When the holder includes the elastic support, the structure can estimate the vertical displacement of the elastic support resulting from the weight of the article, thus allowing appropriate estimation of the vertical displacement of the article resulting from the change in the displacement of the elastic support.

In one aspect, when the holder holding the article is lowered to transfer the article to a transfer area, the control device may decrease an amount by which the holder is lowered by the lifter in response to a greater estimated displacement estimated by the displacement estimator.

In this structure, when the different weights of articles change the displacement of the elastic support for each article, the amount by which the holder is lowered may be adjusted appropriately to allow the article to be lowered to an appropriate height with respect to the transfer area.

The article transport vehicle according to one or more embodiments of the disclosure produces at least one of the effects described above.

What is claimed is:

1. An article transport vehicle for transporting an article, the article transport vehicle comprising:
a holder configured to hold the article;
a lifter configured to raise and lower the holder; and
a control device configured to control the lifter,
wherein the lifter comprises a rotator, a wound member windable around and unwindable from the rotator, and a lifter drive motor configured to rotate the rotator, the lifter configured to raise and lower the holder suspended with the wound member by winding and unwinding the wound member with rotation of the rotator, and
wherein the control device comprises:
a transmission torque detector configured to detect transmission torque transmitted from the lifter drive motor to the rotator, and
a weight estimator configured to estimate a weight of the article held by the holder based on the transmission torque detected by the transmission torque detector.

2. The article transport vehicle according to claim 1, wherein:
the transmission torque detector detects the transmission torque with the lifter stopping raising or lowering the holder or with the lifter raising or lowering the holder at a constant speed.

3. The article transport vehicle according to claim 1, wherein:
the transmission torque detector detects the transmission torque with the holder being stationary at an uppermost position in a lift range of the holder.

4. The article transport vehicle according to claim 1, further comprising:
a traveler connected to the holder and the lifter and configured to travel along a travel path,
wherein the control device further comprises:
a recorder configured to record, before the traveler starts traveling, the weight of the article estimated by the weight estimator as a prestart weight,
a monitor configured to continuously monitor the weight of the article estimated by the weight estimator during travel of the traveler, and
a drop determiner configured to determine that at least a part of the article has dropped in response to a difference between a latest estimated weight of the article monitored by the monitor and the prestart weight being greater than or equal to a predetermined determination threshold.

5. The article transport vehicle according to claim 4, wherein:
the weight estimator estimates the weight of the article based on a value obtained by applying a low-pass filter to a detection value of the transmission torque obtained by the transmission torque detector.

6. The article transport vehicle according to claim 1, wherein:
the holder comprises an article support configured to be in contact with the article to support the article, a connector connected to the lifter, and an elastic support supporting the article support in a vertically elastic manner with respect to the connector, and
the control device further comprises a displacement estimator configured to estimate a vertical displacement of the elastic support based on the weight of the article estimated by the weight estimator.

7. The article transport vehicle according to claim 6, wherein:
when the holder holding the article is lowered to transfer the article to a transfer area, the control device decreases an amount by which the holder is lowered by the lifter in response to a greater estimated displacement estimated by the displacement estimator.
